(19) United States
(12) Patent Application Publication
(10) Pub. No.: US 2026/0043853 A1
(43) Pub. Date: Feb. 12, 2026

(54) VEHICLE BATTERY MONITORING SYSTEM AND METHOD

(71) Applicant: Allstate Insurance Company, Northbrook, IL (US)

(72) Inventor: Howard Hayes, Glencoe, IL (US)

(73) Assignee: Allstate Insurance Company, Northbrook, IL (US)

(21) Appl. No.: 18/799,715

(22) Filed: Aug. 9, 2024

(51) Int. Cl. G01R 31/367; B60L 58/12; B60L 58/16; G01R 31/396

(52) U.S. Cl. CPC G01R 31/367; B60L 58/12; B60L 58/16; G01R 31/396; B60L 2240/12; B60L 2240/14; B60L 2240/662

(57) ABSTRACT

A computing system comprises one or more processors and one or more storage devices that comprise instruction code. The instruction code is executable by the processors to cause the computing system to receive battery characteristic information associated with a battery of a vehicle, receive vehicle usage information associated with the vehicle, and receive vehicle environmental information. The vehicle usage information relates one or more of a speed and acceleration experienced by the vehicle with one or more vehicle operating periods. The vehicle environmental information relates one or more environmental conditions to which the vehicle was exposed with one or more periods. The computing system subsequently determines, via trained machine-learning logic and based on the battery characteristic information, the vehicle usage information, and the vehicle environmental information a battery health associated with the battery that is indicative of a current charge capacity of the battery relative to an original/rated charge capacity of the battery. The computing system communicates an indication of the battery health prediction.

### BACKGROUND

### I. Field

This application generally relates to electric vehicles. In particular, this application relates to a system and method for monitoring the usage of a battery of an electric vehicle.

### II. Description of Related Art

Electric vehicles (EVs) represent a significant shift in the automotive industry towards sustainability and reduced reliance on fossil fuels. At the heart of these vehicles lies their battery technology, which stores and delivers electrical energy to power the vehicle's electric motor. These batteries are typically lithium-ion batteries, known for their high energy density and rechargeability. However, like all batteries, the ones used in electric vehicles degrade over time due to a combination of factors, including usage patterns, environmental conditions, and the chemistry of the battery cells. As an electric vehicle is driven and recharged, the battery undergoes cycles of charging and discharging, causing chemical changes within the cells that gradually reduce their charge capacity to hold a charge. This degradation leads to a decrease in the vehicle's driving range and overall performance over time.

### SUMMARY

In a first aspect, a computing system comprises one or more processors, and one or more storage devices that comprise instruction code that is executable by the one or more processors. The instruction code is executable by the processors to cause the computing system to receive battery characteristic information associated with a battery of a vehicle, receive vehicle usage information associated with the vehicle, and receive vehicle environmental information. The vehicle usage information relates one or more of a speed and acceleration experienced by the vehicle with one or more vehicle operating periods. The vehicle environmental information relates one or more environmental conditions to which the vehicle was exposed with one or more periods. The computing system subsequently determines, via trained machine-learning logic and based on the battery characteristic information, the vehicle usage information, and the vehicle environmental information a battery health associated with the battery that is indicative of a current charge capacity of the battery relative to an original/rated charge capacity of the battery, and communicates an indication of the battery health prediction.

In a second aspect, a non-transitory computer-readable medium has stored there on instruction code that is executable by one or more processors of a computing system to cause computing system to receive battery characteristic information associated with a battery of a vehicle, receive vehicle usage information associated with the vehicle, and receive vehicle environmental information. The vehicle usage information relates one or more of a speed and acceleration experienced by the vehicle with one or more vehicle operating periods. The vehicle environmental information relates one or more environmental conditions to which the vehicle was exposed with one or more periods. The computing system subsequently determines, via trained machine-learning logic and based on the battery characteristic information, the vehicle usage information, and the vehicle environmental information a battery health associated with the battery that is indicative of a current charge capacity of the battery relative to an original/rated charge capacity of the battery, and communicates an indication of the battery health prediction to.

In a third aspect, a computer-implemented method comprises receiving battery characteristic information associated with a battery of a vehicle, vehicle usage information associated with the vehicle, and vehicle environmental information. The vehicle usage information relates one or more of a speed and acceleration experienced by the vehicle with one or more vehicle operating periods. The vehicle environmental information relates one or more environmental conditions to which the vehicle was exposed with one or more periods. The method further comprises determining, via trained machine-learning logic and based on the battery characteristic information, the vehicle usage information, and the vehicle environmental information a battery health associated with the battery that is indicative of a current charge capacity of the battery relative to an original/rated charge capacity of the battery, and communicating an indication of the battery health prediction.

### BRIEF DESCRIPTION OF THE DRAWINGS

The accompanying drawings are included to provide a further understanding of the claims, are incorporated in, and constitute a part of this specification. The detailed description and illustrated examples described serve to explain the principles defined by the claims.

FIG. 1 illustrates an environment that includes various systems/devices that facilitate monitoring the health of the battery of an electric vehicle, in accordance with example embodiments.

FIG. 2 illustrates a mobile device, in accordance with example embodiments.

FIG. 3 illustrates a vehicle, in accordance with example embodiments.

FIG. 4 illustrates a battery health monitoring system (BHMS), in accordance with example embodiments.

FIG. 5 illustrates operations that facilitate predicting the health of the battery of an electric vehicle, in accordance with example embodiments.

FIG. 6 illustrates examples of operations that facilitate training machine-learning (ML) logic to predict the health of the battery of an electric vehicle, in accordance with example embodiments.

FIG. 7 illustrates operations that facilitate providing battery health information to one or more remote systems or devices, in accordance with example embodiments.

FIGS. 8A and 8B illustrate a user interface that facilitates providing vehicle information to a user of a remote device, in accordance with example embodiments.

FIG. 9 illustrates a computer system that can form part of or implement any of the systems and/or devices described above, in accordance with example embodiments.

### DETAILED DESCRIPTION

Various examples of systems, devices, and/or methods are described herein. Any embodiment, implementation, and/or feature described herein as being an “example” is not necessarily to be construed as preferred or advantageous over any other embodiment, implementation, and/or feature unless stated as such. Thus, other embodiments, implementations, and/or features may be utilized, and other changes may be made without departing from the scope of the subject matter presented herein.

Accordingly, the examples described herein are not meant to be limiting. It will be readily understood that the aspects of the present disclosure, as generally described herein, and illustrated in the figures, can be arranged, substituted, combined, separated, and designed in a wide variety of different configurations.

Further, unless the context suggests otherwise, the features illustrated in each of the figures may be used in combination with one another. Thus, the figures should be generally viewed as component aspects of one or more overall embodiments, with the understanding that not all illustrated features are necessary for each embodiment.

Additionally, any enumeration of elements, blocks, or steps in this specification or the claims is for purposes of clarity. Thus, such enumeration should not be interpreted to require or imply that these elements, blocks, or steps adhere to a particular arrangement or are carried out in a particular order.

Further, terms such as “A coupled to B” or “A is mechanically coupled to B” do not require members A and B to be directly coupled to one another. It is understood that various intermediate members may be utilized to “couple”members A and B together.

Moreover, terms such as “substantially” or “about” that may be used herein, are meant that the recited characteristic, parameter, or value need not be achieved exactly but that deviations or variations, including, for example, tolerances, measurement error, measurement accuracy limitations and other factors known to skill in the art, may occur in amounts that do not preclude the effect the characteristic was intended to provide.

### III. Introduction

As noted above, batteries in electric vehicles degrade over time due to a combination of factors, including usage patterns, environmental conditions, and the chemistry of the battery cells. As an electric vehicle is driven and recharged, the battery undergoes cycles of charging and discharging, causing chemical changes within the cells that gradually reduce their charge capacity to hold a charge. This degradation leads to a decrease in the vehicle's driving range and overall performance over time.

Disclosed herein are example battery health monitoring systems (BHMS) and methods performed by the systems that facilitate determining the battery health of an electric vehicle. In some examples, the battery health is indicative of the ratio of the maximum charge capacity of the battery to the battery's initial/rated charge capacity. Some examples of the system are configured to receive battery characteristics, vehicle usage, and vehicle environmental information associated with a vehicle and determine or predict the battery health of the battery based on this information. In some examples, the prediction is subsequently communicated to one or more other subsystems of the BHMS or other systems that may include remote systems. For example, the prediction may be subsequently communicated to a mobile device (e.g., phone, tablet, etc.), an on-board diagnostic (OBD) system of a vehicle, etc.

Some examples of the battery characteristic information specify information such as the original/rated charge capacity of the battery, the battery type, the battery serial number, the number of times the battery was charged, the charger type used to charge the battery, etc. Some examples of the vehicle usage information specify one or more kinematic characteristics of the vehicle such as its speed and acceleration, and relate the kinematic characteristics with one or more vehicle operating periods. Some examples of the vehicle environmental information relate one or more environmental conditions (e.g., temperatures, humidities, etc.) to which the vehicle was exposed with one or more periods.

In some examples, the BHMS receives the battery characteristics and perhaps vehicle usage information from a vehicle information server. For example, the BHMS may communicate vehicle-identifying information that specifies a particular vehicle to the vehicle information server. The vehicle information server may then communicate battery characteristic information associated with the particular vehicle to the BHMS.

In some examples, the BHMS receives the vehicle environmental information from an environmental information server that stores environmental information associated with different regions and over different periods. For example, the BHMS may communicate to the environmental information server a request for environmental information associated with one or more locations at which the vehicle was located during the one or more periods. The environmental information server may then communicate vehicle environment information associated with the one or more locations at which the vehicle was located during the one or more periods to the BHMS.

In some examples, the BHMS 105 may generate a user interface that facilitates providing a cost or trade-in value, an insurance quote, a cost and terms for an extended warranty, etc., for the vehicle that is determined based in part on the predicted battery health. For instance, some examples of the BHMS 105 may comprise a database with records that relate various electric vehicles having batteries of known battery health with various cost or trade-in values, insurance rates, etc. After determining the battery health for a particular vehicle, the BHMS may search the database for a matching record and specify the corresponding cost or trade-in value, insurance quote, extended warranty, etc., for the vehicle to a user via the user interface.

### IV. Example Environment

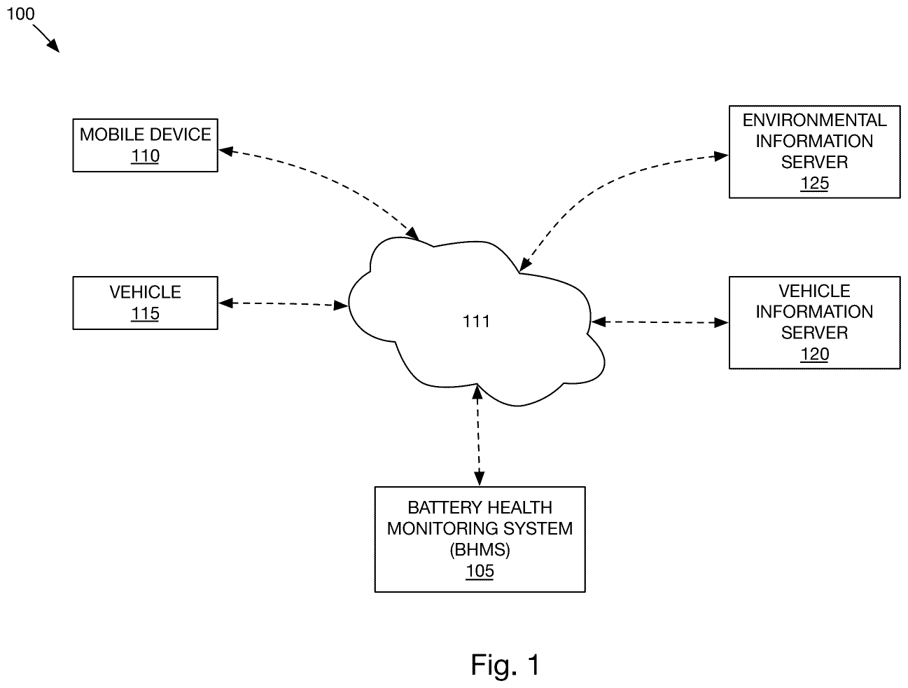

FIG. 1 illustrates an example of an environment 100 that includes various systems/devices that facilitate monitoring the health of the battery of an electric vehicle 115. Example systems/devices of the environment include a battery health monitoring system 105 (BHMS), a mobile device 110, a vehicle 115, a vehicle information server 120, and an environmental information server 125. As described in further detail below, the BHMS 105 is configured to receive one or more of battery characteristic information associated with a battery of the vehicle 115, vehicle usage information associated with the vehicle 115, and vehicle environmental information associated with the vehicle 115 and to predict the health or remaining charge capacity of the battery based on the received information. The predicted battery health may then, for example, be communicated to a user who may be interested in purchasing the vehicle 115 and/or in obtaining insurance for the vehicle 115. In an example, the BHMS 105, mobile device 110, vehicle 115, vehicle information server 120, and environmental information server 125 communicate information to one another via a communication network 111, such as the Internet, a cellular communication network, a WiFi network, etc.

a. Example Mobile Devices

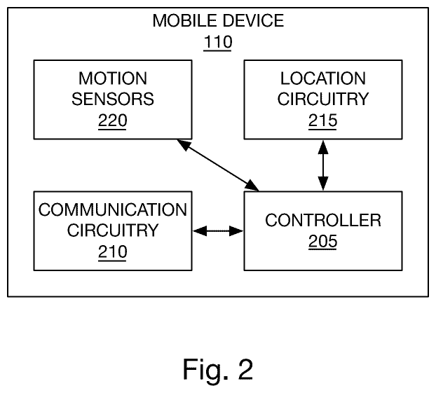

FIG. 2 illustrates an example of a mobile device 110. Some examples of the mobile device 110 correspond to cellular telephones, tablets, etc. Some examples of the mobile device 110 communicate via a cellular telephone network, such as GSM, LTE, 5G, etc., cellular networks. As shown in the figure, some examples of the mobile device 110 include a controller 205, communication circuitry 210, location circuitry 215, and one or more motion sensors 220.

Some examples of the controller 205 comprise a processor and a memory that is in communication with the processor. The processor is configured to execute instruction code stored in the memory. The instruction code facilitates performing, by the mobile device 110, various operations that are described herein. In this regard, the instruction code may cause the processor to control and coordinate various activities performed by the different subsystems of the mobile device 110. Some examples of the processor correspond to an ARM®, Intel®, AMD®, PowerPC®, etc., based processor. Some examples of instruction code stored in the memory and executed by the processor implement an operating system, such as Android™, IOS®, Windows®, Linux®, or a different operating system.

Some examples of the communication circuitry 210 comprise circuitry that facilitates wired and/or wireless communications with other devices or systems. An example of the wireless communication circuitry includes cellular telephone communication circuitry configured to communicate information over a cellular telephone network such as a 3G, 4G, and/or 5G network. Other examples of the wireless communication circuitry facilitate communication of information via an 802.11 based network, Bluetooth®, Zigbee®, near-field communication technology or a different wireless network.

Some examples of the location circuitry 215 correspond to global positioning system circuitry (GPS circuitry) configured to determine the geographic location of the mobile device 110. Some examples of the location circuitry periodically (e.g., every second) determine location information associated with the mobile device 110, such as the latitude and longitude of the mobile device 110 at different times. In some examples, location information communicated by the mobile device 110 includes one or more latitude/longitude locations determined by the location circuitry. Some examples of the location circuitry facilitate determining the location of the mobile device 110 via techniques that involve triangulation to determine the location of the mobile device 110. For example, the location circuitry determines, based on the relative signal strength of various cellular towers having known locations, the location of the mobile device 110.

Some examples of the motion sensors 220 facilitate detecting movement of the mobile device 110. In this regard, some examples of the motion sensors 220 correspond to multi-axis accelerometers, compasses, speedometers, vibration sensors, gyroscopic sensors, etc.

In some examples, the mobile device 110 associates the location and motion information with a vehicle 115. For example, the location and motion information may be associated with the vehicle 115 after the mobile device 110 establishes communications (e.g., via a BT connection) with the vehicle 115. In some examples, a user of the mobile device 110 can indicate via an application operating on the mobile device 110 that the mobile device 110 is in a particular vehicle 115 (e.g., a vehicle registered to the user) and after receiving the indication, the mobile device 110 associates the location and motion information and the vehicle 115.

In operation, when the mobile device 110 is situated within a vehicle 115, one or more readings from the location circuitry and/or the motion sensors 220 can be used to ascertain the vehicle's position as well as its kinematic characteristics, such as the vehicle's speed, acceleration direction of acceleration, etc. This information can, in turn, be used to determine one or more routes the vehicle 115 has taken, whether the vehicle 115 has been in an accident, the accident force and angle of impact, etc. In some examples, the information gathered by the mobile device 110 and associated with the vehicle 115 is uploaded to the vehicle information server 120, the BHMS 105, and/or other systems.

b. Example Vehicles

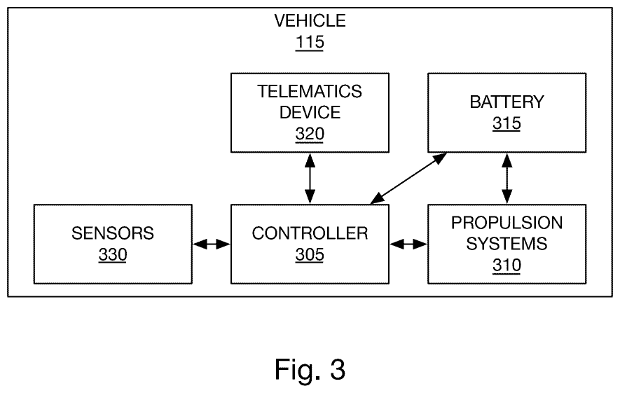

FIG. 3 illustrates an example of a vehicle 115. Some examples of the vehicle 115 correspond to an automobile, motorcycle, watercraft, aircraft, or a different type of vehicle 115. As shown in the figure, some examples of the vehicle 115 include a controller 305, a propulsion system 310, a battery 315, a telematics device 320, and one or more sensors 330.

Some examples of the controller 305 comprise a processor and a memory and/or data storage device that is in communication with the processor. The processor is configured to execute instruction code stored in the memory. The instruction code facilitates performing, by the vehicle 115, various operations that are described herein. In this regard, the instruction code may cause the processor to control and coordinate various activities performed by the different subsystems of the vehicle 115. Some examples of the processor correspond to an ARM®, Intel®, AMD®, PowerPC®, etc., based processor. Some examples of instruction code stored in the memory and executed by the processor implement an operating system, such as Android™, IOS®, Windows®, Linux®, or a different operating system.

Some examples of the propulsion system 310 comprise one or more electric motors, such as induction motors that derive power/energy from the battery 315. Such motors operate by inducing a rotating magnetic field in the stator (the stationary part) of the motor, which interacts with conductors in the rotor (the rotating part), causing it to rotate and thus propel the vehicle 115. Some examples of the motor can achieve high levels of efficiency, especially when operated at variable speeds. This efficiency helps to maximize the range of the vehicle 115 by minimizing energy loss during operation. Some examples of the motors support regenerative braking, wherein the motor acts as a generator to convert kinetic energy of the vehicle 115 back into electrical energy during braking or deceleration. This energy is then stored in the battery 315 of the vehicle 115, enhancing the overall energy efficiency of the vehicle 115.

Some examples of the battery 315 comprise a relatively large number of rechargeable battery cells such as lithium-ion battery cells, nickel-metal hydride (NiMH) battery cells, solid-state battery cells, etc. The battery cells are connected in series and parallel configurations to achieve the desired voltage and charge capacity for the vehicle 115. The battery 315 may be charged using various methods, including standard household outlets, dedicated charging stations, fast-charging stations, etc. Charging times vary depending on the charging method and the battery's charge capacity. Some examples of the battery 315 include charge/discharge circuitry that regulates charging and discharging processes, monitors individual cell voltages and temperatures and protects against overcharging, over-discharging, and overheating.

As noted above, some examples of the battery 315 degrade over time due to factors such as usage, charging cycles, and environmental conditions. As such, the maximum charge capacity of the battery 315 relative to the original/rated charge capacity of the battery 315 may degrade over time. For example, the maximum charge capacity of a particular battery 315 of a vehicle 115 having an initial/rated charge capacity of 85 kWh may degrade to 70-80% of its original charge capacity over 8 to 10 years or after a certain number of charging cycles, whichever comes first.

In some examples, the maximum charge capacity of the battery 315 is determined based on one or more factors, such as the estimated number of coulombs that were able to be stored in the battery 315 during a charge cycle (as determined by the flow of current over time into the battery 315), the distance the vehicle 115 was able to travel on a single charge, etc. In some examples, the determined maximum charge capacity of the battery 315 is stored in a storage device of the battery 315 charge/discharge circuitry. In some examples, the maximum charge capacity of the battery 315 is additionally or alternatively stored in a storage device in communication with the controller 305 and/or the telematics device 320. In some examples, an indication of the battery's health is stored within the storage device of the battery charge/discharge circuitry, a storage device in communication with the controller 305, and/or in the telematics device 320. In some examples, the indication of the battery health corresponds to the ratio of the determined maximum charge capacity of the battery 315 to the battery's initial/rated charge capacity. For example, the battery health indication for a new battery 315 may be 100%, whereas the battery health indication for the same battery 315 after 8 to 10 years of usage may be 75%.

Some examples of the telematics device 320 collect and wirelessly communicate data about that vehicle's performance and location. In this regard, some examples of the telematics device 320 are configured to communicate (e.g., via the onboard diagnostic (OBD) port of the vehicle 115) with the controller 305 of the vehicle 115 to obtain information that is sensed/recorded by one or more of the sensors 330. In some examples, information collected by the telematics device 320 is communicated to an insurance processing server (IPS) and analyzed by the IPS to facilitate determining an appropriate and/or personalized insurance policy for the driver of the vehicle 115. Such a policy may encourage the driver to adopt safe driving practices, which, in some instances, can lead to lower insurance premiums for the driver.

Some examples of the telematics device 320 comprise circuitry that facilitates wireless communications with other devices or systems. An example of the wireless communication circuitry includes cellular telephone communication circuitry configured to communicate information over a cellular telephone network such as a 3G, 4G, and/or 5G network. Other examples of the wireless communication circuitry facilitate communication of information via an 802.11 based network, Bluetooth®, Zigbee®, near-field communication technology or a different wireless network. Some examples of the telematics device 320 comprise location circuitry (e.g., circuitry that receives signals from one or more global navigation satellite systems (GNSSs)), which facilitates real-time location tracking of the vehicle 115.

Some examples of the sensors 330 are configured to sense/record various aspects associated with the vehicle 115. For instance, some examples of the sensors 330 are configured to obtain values associated kinematic characteristics of the vehicle 115, such as its speed, direction, rate of acceleration or deceleration, distance traveled, whether there were instances of sudden acceleration, braking, swerving, etc. Some examples of sensors 330 and/or circuitry that facilitate determining the kinematic characteristics correspond to multi-axis accelerometers, compasses, speedometers, vibration sensors, gyroscopic sensors, location circuitry (e.g., GNSS), etc.

Some examples of the sensors 330 are configured to obtain values associated with environmental characteristics associated with the environment in which the vehicle 115 is operated/exposed, such as its geographic location, outside temperature, precipitation types and amounts, etc. Some examples of sensors 330 and/or circuitry that facilitate determining the environmental characteristics correspond to temperature sensors, humidity sensors, pressure sensors, light sensors, etc.

Some examples of the sensors 330 are configured to obtain values associated with peripheral usage characteristics of the vehicle 115, such as airbag deployment, headlight usage, brake light operation, door opening and closing, door locking and unlocking, cruise control usage, hazard lights usage, windshield wiper usage, horn usage, turn signal usage, seat belt usage, phone and radio usage within the vehicle 115, autonomous driving system usage. Some examples of the sensors 330 sense/record other characteristics of the vehicle 115, such as the status of its propulsion system 310 (e.g., motor RPM, amount of electrical current, voltage, temperature, etc.), odometer reading, the maximum charge capacity of the battery 315 and/or an indication of the battery health, software upgrades, tire pressure readings, indications of maintenance performed on the vehicle 115, etc.

In some examples, one or more readings sensed by the sensors 330 are associated with a timestamp. The timestamp facilitates determining afterward a particular period during which particular sensed values were captured.

In some examples, values obtained by the sensors 330 are stored within the vehicle 115. For instance, in some examples, the obtained values associated with the kinematic, environmental, and/or peripheral usage characteristics of the vehicle 115 are stored in a non-volatile storage device in communication with the controller 305 and/or within the telematics device 320. In some examples, the values obtained by the sensors 330 are communicated to one or more other subsystems of the BHMS or other systems, including remote systems (e.g., a mobile device, an OBD system of a vehicle, etc.) for storage and/or for further analysis. For example, the controller 305 and/or the telematics device may directly or indirectly (e.g., via the mobile device 110) communicate the obtained values to the BHMS 105, the vehicle information server 120, etc. In some examples, one or more of the values obtained by the sensors are communicated to the other subsystems or systems in real-time, uploaded to the other subsystems or systems according to a schedule (e.g., once a week), and/or uploaded to the other subsystems or systems when a storage device of the vehicle 115 upon which the values are stored becomes full.

c. Example Battery Health Monitoring System

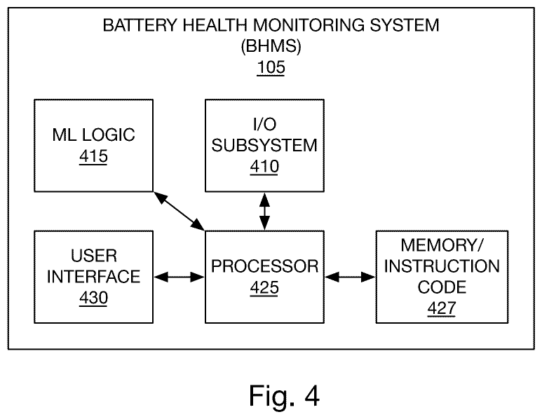

FIG. 4 illustrates an example of a battery health monitoring system 105 (BHMS). Referring to the figure, the BHMS 105 includes a memory 427, a processor 425, a user interface 430, an input/output (I/O) subsystem 410, and ML logic 415.

The processor 425 is in communication with the memory 427 and is configured to execute instruction code stored in the memory 427. The instruction code facilitates performing, by the BHMS 105, various operations that are described herein. In this regard, some examples of the instruction code cause the processor 425 to control and coordinate various activities performed by the different subsystems of the BHMS 105. Some examples of the processor 425 correspond to a stand-alone computer system such as an ARM®, Intel®, AMD®, or PowerPC® based computer system or a different computer system and can include application-specific computer systems. Some examples of the computer system include an operating system. Examples of the operating system include Android™, Windows®, Linux®, Unix®, or a different operating system.

Some examples of the I/O subsystem 410 include one or more input/output interfaces configured to facilitate communications with entities outside of the BHMS 105. Some examples of the I/O subsystem 410 include wireless communication circuitry configured to facilitate communicating information to and from the BHMS 105. Examples of the wireless communication circuitry include cellular telephone communication circuitry configured to communicate information over a cellular telephone network such as a 3G, 4G, and/or 5G network. Other examples of the wireless communication circuitry facilitate the communication of information via a WiFi-based network, Bluetooth®, Zigbee®, near-field communication technology or a different wireless network.

Some examples of the I/O subsystem 410 are configured to communicate information via a RESTful API or a Web Service API. Some examples of I/O subsystem 410 implement a web server to facilitate generating one or more web-based interfaces through which users of the BHMS 105 and/or other systems interact with the BHMS 105.

Some examples of the ML logic 415 are configured to, alone or in combination with other subsystems of the BHMS 105, predict the battery health associated with the battery 315 of a vehicle 115 based on various received factors such as the charge capacity of the battery 315, battery characteristic information associate with the battery, the vehicle usage information associated with the vehicle 115, and the vehicle environmental information associated with the vehicle 115. For instance, in some examples, the BHMS 105 is configured to generate a plurality of embeddings that respectively represent the battery charge capacity of the battery 315, the battery characteristic information, the vehicle usage information, and the vehicle environmental information. The generated embeddings are then provided as input to one or more nodes of an input layer of a neural network implemented by the ML logic 415. One or more output nodes of the output layer of the neural network represent the predicted health of the battery 315. In this regard, some examples of the ML logic 415 include hardware, software, or a combination thereof that is specifically configured to implement or assist in the implementation of various supervised and unsupervised machine learning models. Within examples, these can involve the implementation of a Holt-Winters algorithm, an exponential time smoothing (ETS) algorithm, an artificial neural network (ANN), a recurrent neural network (RNN), convolutional neural network (CNN), a seasonal autoregressive moving average (SARIMA) algorithm, a network of long short-term memories (LSTM), a gated recurring unit (GRU) algorithm. Examples of the ML logic 415 can implement other machine learning (ML) logic and/or AI algorithms.

As described in further detail below, some examples of the ML logic 415 are trained to predict the battery health of a battery 315 based on its associated battery characteristic information, vehicle usage information, and vehicle environmental information. In this regard, in some examples, the ML logic 415 is trained by iteratively adjusting weights and biases of nodes of a neural network implemented by the ML logic 415 (e.g., via backpropagation and forward propagation techniques) until the output of the ML logic 415 makes the correct prediction regarding the training data. That is, the weights and biases of the ML logic 415 are adjusted so that when training data that indicates battery characteristic information, vehicle usage information, and vehicle environmental information for a particular battery 315 is input into the ML logic, the ML logic 415 outputs a prediction of the battery health that substantially matches the known battery health of the battery 315.

### V. Example Operations

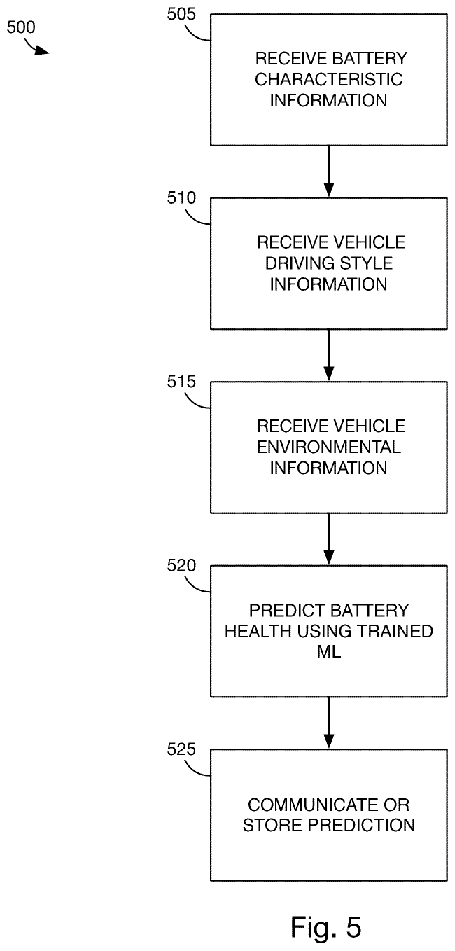

FIG. 5 illustrates examples of operations 500 that facilitate determining the health of the battery 315 of an electric vehicle 115. These operations are performed by some examples of the systems described above (e.g., the BHMS 105, the mobile device 110, the vehicle, etc.). In some examples, one or more of these operations are implemented via instruction code, stored in corresponding data storage (e.g., memory 427) of these systems. Execution of the instruction code by corresponding processors of the systems causes these systems to perform these operations alone or in combination with other systems and/or devices.

The operations at block 505 involve the BHMS 105 receiving battery characteristic information associated with a battery 315 of a vehicle 115. Some examples of the battery characteristic information specify static information, such as the original/rated charge capacity of the battery 315, the battery type and/or serial number of the battery 315. Some examples of the battery type may indicate the battery chemistry (e.g., lithium-ion battery, solid-state battery, etc.), the number of battery cells within the battery 315 (e.g., one hundred cells), the manufacturer of the battery cells, etc. Some examples of the battery characteristic information specify dynamic information such as the number of times the battery 315 was charged, and the types of chargers used to charge the battery 315 (e.g., 120 or 240 volt home charger, DC fast charger), etc.

In some examples, the battery characteristic information is stored in one or more of the battery 315, the vehicle, and/or the telematics device 320 and the BHMS 105 communicates with the vehicle 115 via the telematics device 320 and/or the mobile device 110 to receive the battery characteristic information.

In some examples, the BHMS 105 receives some or all of the battery characteristics from a vehicle information server 120. For instance, in some examples, the BHMS 105 receives, from the vehicle, the serial number and/or battery type associated with the battery 315 of the vehicle 115 and obtains other battery characteristics from a database of the vehicle information server 120 (e.g., from a vehicle information server 120 of the vehicle manufacture). For example, the BHMS may, via a telematics device 320 coupled to the ODB port of the vehicle 115 and/or the mobile device 110, receive the serial number and/or battery type of the battery 315 of the vehicle 115. The BHMS 105 may then communicate a network request to the vehicle information server 120 that specifies the serial number, battery type, perhaps authentication information, and one or more requested battery characteristics. The vehicle information server 120 may responsively communicate the information associated with the requested battery characteristics to the BHMS 105. In some examples, the BHMS 105 obtains a vehicle identification number (VIN) that uniquely specifies the vehicle 115 and communicates the VIN to the vehicle information server 120. The vehicle information server 120 then responsively communicates the battery characteristics associated with the vehicle that are specified by the VIN to the BHMS 105.

The operations at block 510 involve the BHMS 105 receiving vehicle usage information associated with the vehicle 115. Some examples of the vehicle usage information relate one or more kinematic characteristics of the vehicle 115 that are sensed/recorded by one or more sensors 330 of the vehicle 115 with one or more vehicle operation periods. Some examples of the sensed/recorded kinematic characteristics include the vehicle's speed, direction, rate of acceleration or deceleration, distance traveled, whether there were instances of sudden acceleration, braking, swerving, etc. In some examples, one or more timestamps are associated with the sensed characteristics. In some examples, the vehicle usage information is stored in one or more of the vehicle 115 and/or the telematics device 320, and the BHMS 105 communicates with the vehicle 115 via the telematics device 320 and/or the mobile device 110 to receive the vehicle usage information.

The operations at block 515 involve the BHMS 105 receiving vehicle environmental information associated with the vehicle 115. Some examples of the vehicle environmental information relate one or more environmental conditions to which the vehicle 115 was exposed (e.g., temperature, humidity, etc.) with one or more periods. In some examples, the vehicle environmental information is sensed/recorded by one or more sensors 330 of the vehicle 115. In some examples, the vehicle environmental information is stored in one or more of the vehicle 115 and/or the telematics device 320, and the BHMS 105 communicates with the vehicle 115 via the telematics device 320 and/or the mobile device 110 to receive the vehicle environmental information.

In some examples, the BHMS 105 receives some or all of the vehicle environmental information from a database of an environmental information server 125. In this regard, in some examples, the BHMS 105 receives information indicative of the location of the vehicle 115 during various periods (e.g., via the GPS of a mobile device 110, a telematics device 320, and/or the vehicle). The BHMS 105 may then communicate a network request to the environmental information server 125 that specifies the vehicle location, the period associated with the vehicle location, perhaps authentication information, and one or more requested environmental characteristics. The environmental information server 125 may responsively communicate the information associated with the requested environmental characteristics to the BHMS 105.

The operations at block 520 involve the BHMS 105 predicting the battery health associated with the battery 315 based on the received factors. For instance, in some examples a plurality of embeddings that respectively represent the battery characteristic information, the vehicle usage information, and the vehicle environmental information are generated. Some examples of the embeddings correspond to a vector having a number of elements that corresponds to the number of characteristics considered in predicting the battery health. Each element of the vector may correspond to a value that represents a particular characteristic. In this regard, some examples of the embedding values may correspond to a range of values to represent a particular characteristic defined by a range of values. Some examples of the embedding values may correspond to enumerations to represent a particular characteristic defined by one or more states.

The generated embeddings are then provided as input to one or more nodes of an input layer of a neural network. One or more output nodes of the output layer represent the predicted health of the battery 315. For example, the value of an output node may correspond to a range between zero and one, where one indicates the battery 315 has 100% of its rated charge capacity, 0.5 indicates the battery 315 has 50% of its rated charge capacity, etc.

The operations at block 525 involve the BHMS 105 communicating or storing an indication of the battery health prediction. For instance, some examples of the BHMS 105 store the battery health prediction locally, for example, in a non-volatile storage device of the BHMS 105. Additionally, or alternatively, some examples of the BHMS 105 communicate the indication to the mobile device 110, the vehicle information server 120, and/or the vehicle 115 (e.g., via the mobile device 110 and/or a telematics device 320).

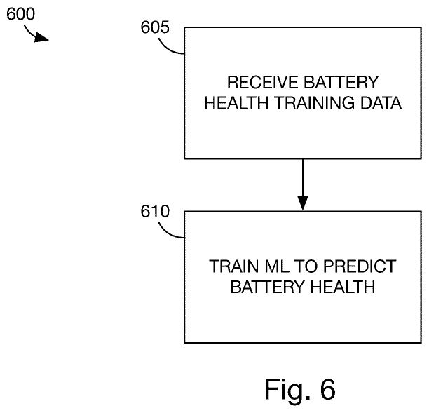

FIG. 6 illustrates examples of operations 600 that facilitate training ML logic 415 to predict the battery health. These operations are performed by some examples of the systems described above (e.g., the BHMS 105). In some examples, one or more of these operations are implemented via instruction code, stored in corresponding data storage (e.g., memory 427) of these systems. Execution of the instruction code by corresponding processors of the systems causes these systems to perform these operations alone or in combination with other systems and/or devices.

The operations at block 505 involve the BHMS 105 receiving training data. Examples of the training data comprise records, where each record relates a particular battery's health with corresponding battery characteristic information, vehicle usage information, and vehicle environmental information. For example, a first record may relate the battery 315 of a particular vehicle 115 and having a known health (e.g., 85% of rated charge capacity) with corresponding battery characteristic information associated with the battery 315, usage information associated with the vehicle, and vehicle environmental information associated with the vehicle 115. Some examples of the battery characteristic information specified in the record specify static information, such as the original/rated charge capacity of the battery 315, the battery type and/or serial number of the battery 315. Some examples of the battery type may indicate the battery chemistry (e.g., lithium-ion battery, solid-state battery, etc.), the number of battery cells within the battery 315 (e.g., one hundred cells), the manufacturer of the battery cells, etc. Some examples of the battery characteristic information specified in the record specify dynamic information such as the number of times the battery 315 was charged and the types of chargers used to charge the battery 315 (e.g., 120 or 240 volt home charger, DC fast charger), etc.

Some examples of the vehicle usage information specified in the record specify kinematic characteristics of the vehicle 115, such as the vehicle's speed, direction, rate of acceleration or deceleration, distance traveled, whether there were instances of sudden acceleration, braking, swerving, etc. Some examples of the vehicle environmental information specified in the record specify one or more environmental conditions to which the vehicle 115 was exposed, such as various temperatures and humidities to which the vehicle 115 was exposed.

The operations at block 510 involve the BHMS system 105 training the ML logic 415 so that the ML logic 415 predicts the battery health of a battery 315 based on its associated battery characteristic information, vehicle usage information, and vehicle environmental information. In this regard, in some examples, the ML logic 415 is trained by iteratively adjusting weights and biases of nodes of the neural network implemented by the ML logic 415 (e.g., via backpropagation and forward propagation techniques) until the output node of the neural network makes the correct prediction regarding the training data. That is, the weights and biases of the neural network are adjusted so that when training data that indicates battery characteristic information, vehicle usage information, and vehicle environmental information for a particular battery 315 is input into the ML logic, the ML logic 415 outputs a prediction of the battery health that substantially matches the known battery health of the battery 315.

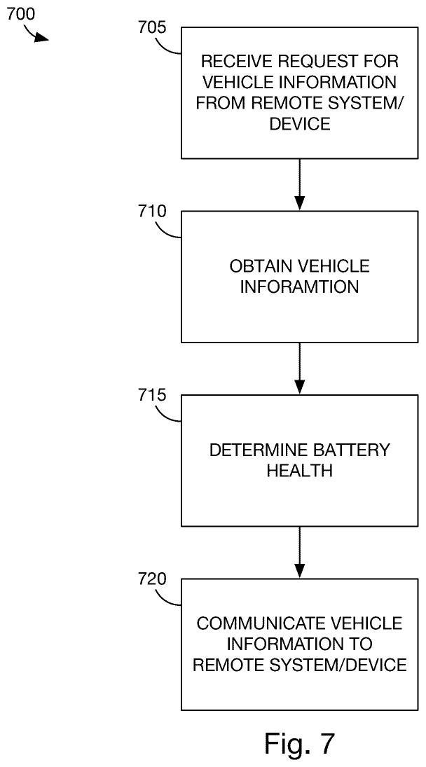

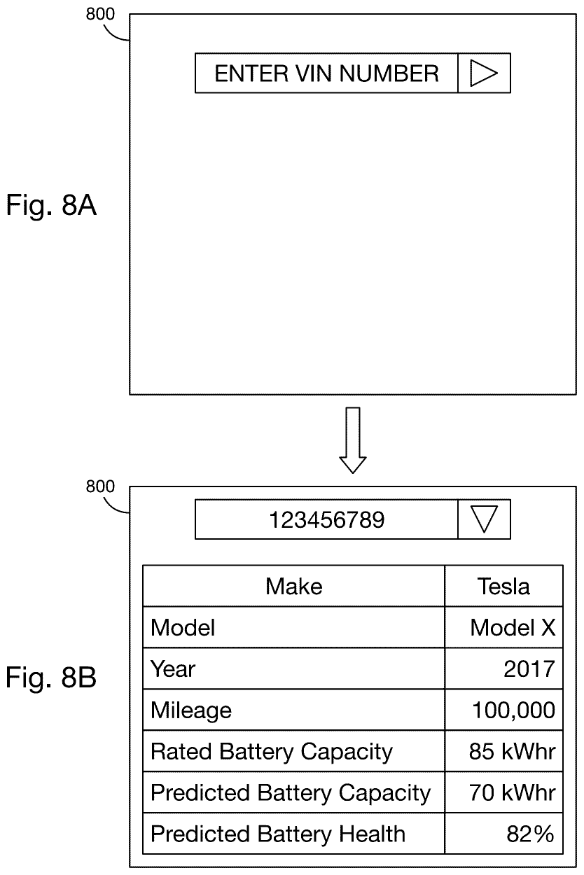

FIG. 7 illustrates examples of operations 700 that may be performed by some systems described above to facilitate providing battery health information to one or more other subsystems or systems, including remote systems, or devices. These operations are performed by some examples of the systems described above (e.g., the BHMS 105, the mobile device 110, the vehicle, etc.). In some examples, one or more of these operations are implemented via instruction code, stored in corresponding data storage (e.g., memory 427) of these systems. Execution of the instruction code by corresponding processors of the systems causes these systems to perform these operations alone or in combination with other systems and/or devices. The operations are best understood with regard to the user interface 800 illustrated in FIGS. 8A and 8B.

The operations at block 705 involve the BHMS 105 receiving a request for information associated with a particular vehicle 115. In some examples, the BHMS 105 implements a web server, and the web server generates a web page that depicts the user interface shown in FIG. 8A. An example of the web page includes a control that facilitates specifying vehicle identifying information such as a vehicle identification number (VIN) that uniquely specifies the vehicle 115 and information such as the year the vehicle 115 was built, the vehicle manufacturer, etc. A user may then specify the vehicle identifying information (e.g., VIN 123456789).

The operations at block 710 involve the BHMS 105 obtaining the vehicle information. For instance, in some examples, the BHMS 105 communicates a request that specifies the vehicle identifying information to a vehicle information server 120 and the vehicle information server 120, in turn, returns the requested information. Some examples of the information include the values obtained by one or more sensors 330 of the vehicle 115. For example, the information may include the kinematic, environmental, and/or peripheral usage characteristics associated with the vehicle 115. In some examples, the BHMS 105 communicates the request directly to the vehicle 115 and/or the telematics device 320 of the vehicle 115, and the vehicle 115 and/or the telematics device 320, in turn, returns the requested information. For instance, in some examples, the vehicle identifying information is associated with a network address that is, in turn, associated with a particular vehicle 115 and/or telematics device 320. The network address facilitates networked communications with the vehicle and/or telematics device 320.

The operations at block 715 involve the BHMS 105 determining the battery health associated with the battery 315 of the vehicle 115. For instance, some examples of the BHMS 105 generate an embedding based on kinematic, environmental, and/or peripheral usage characteristics of the vehicle 115 specified in the vehicle information. The generated embedding is then provided as input to one or more nodes of an input layer of a neural network implemented by ML logic 415 of the BHMS 105. One or more output nodes of the neural network then provide a predicted health of the battery 315. For example, the value of an output node may correspond to a range between zero and one, where one indicates the battery 315 has 100% of its rated charge capacity, 0.5 indicates the battery 315 has 50% of its rated charge capacity, etc.

The operations at block 715 involve the BHMS 105 communicating some or all of the vehicle information and the battery health indication to the other subsystems, systems and/or devices. For example, as shown in FIG. 8B, the BHMS 105 may update the user interface 800 to display some or all of the vehicle information and the battery health indication that is associated with the vehicle identifying information. For example, the user interface may be updated to display static vehicle characteristics such as the make and model, the rated battery charge capacity, etc. The user interface may be updated to display dynamic vehicle characteristics such as the mileage and also to display a predicted battery charge capacity which is based on the predicted battery health.

In some examples, the BHMS 105 may generate a user interface that facilitates providing a risk assessment, an insurance quote based on the risk assessment, etc., for the vehicle 115 that is based in part on the predicted battery health. For instance, some examples BHMS 105 may comprise a database with records that relate various electric vehicles having batteries of known battery health with various risk levels indicative of the risk associated with insuring the vehicle 115. The risk level may be based on other factors beyond just the determined/predicted health of the battery, such as the estimated cost and/or availability of a replacement battery, the costs associated with installing the battery, the availability of service centers capable of replacing the battery, etc. The risk level, in turn, may be associated with particular type of insurance, insurance rate, an extended warranty, etc. In general, for any particular make and model, the cost of insuring the vehicle 115 may decrease with increased battery health. In some examples, the ML logic 415 of the BHMS 105 is additionally trained on these records to infer/predict a risk level for a particular vehicle 115 having particular kinematic, environmental, and/or peripheral usage characteristics.

In some examples, the BHMS 105 may generate a user interface that facilitates providing a cost or trade-in value for the vehicle 115 that is based in part on the predicted battery health. For instance, some examples BHMS 105 may comprise a database with records that relate various electric vehicles having batteries of known battery health with various trade-in values. In general, for any particular make and model, the cost or trade-in value of the vehicle 115 may increase with increased battery health. In some examples, the ML logic 415 of the BHMS 105 is additionally trained on these records to infer a cost or trade-in value for a particular vehicle 115 having particular kinematic, environmental, and/or peripheral usage characteristics.

### VI. Example Computer Systems

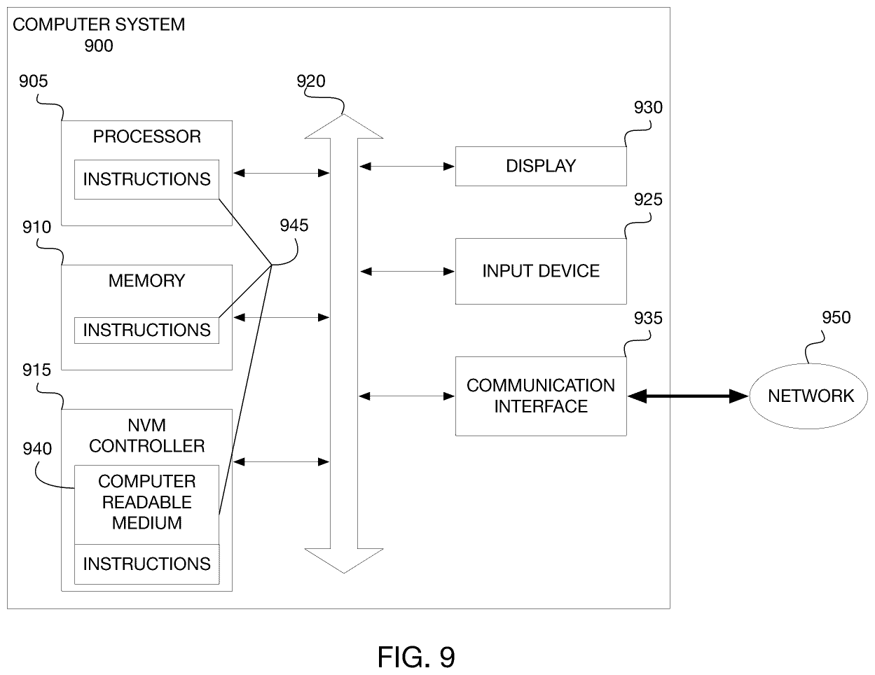

FIG. 9 illustrates an example of a computer system 900 that can form part of or implement any of the systems and/or devices described above. The computer system 900 can include a set of instructions 945 that the processor 905 can execute to cause the computer system 900 to perform any of the operations described above. An example of the computer system 900 can operate as a stand-alone device or can be connected, e.g., using a network, to other computer systems or peripheral devices.

In a networked example, the computer system 900 can operate in the charge capacity of a server or as a client computer in a server-client network environment, or as a peer computer system in a peer-to-peer (or distributed) environment. The computer system 900 can also be implemented or incorporated into various devices, such as a personal computer or a mobile device, capable of executing instructions 945 (sequential or otherwise), causing a device to perform one or more actions. Further, each of the systems described can include a collection of subsystems that individually or jointly execute a set, or multiple sets, of instructions to perform one or more computer operations.

The computer system 900 can include one or more memory devices 910 communicatively coupled to a bus 920 for communicating information. In addition, code operable to cause the computer system to perform operations described above can be stored in the memory 910. The memory 910 can be random-access memory, read-only memory, programmable memory, or any other type of memory or storage device.

The computer system 900 can include a display 930, such as a liquid crystal display (LCD), organic light-emitting diode (OLED) display, or any other display suitable for conveying information. The display 930 can act as an interface for the user to see processing results produced by processor 905.

Additionally, the computer system 900 can include an input device 925, such as a keyboard or mouse or touchscreen, configured to allow a user to interact with components of system 900.

The computer system 900 can also include a non-volatile memory (NVM) controller 915. The NVM controller 915 can include a computer-readable medium 940 (e.g., flash drive) in which the instructions 945 can be stored. The instructions 945 can reside completely, or at least partially, within the memory 910 and/or within the processor 905 during execution by the computer system 900. The memory 910 and the processor 905 also can include computer-readable media, as discussed above.

The computer system 900 can include a communication interface 935 to support communications via a network 950. The network 950 can include wired networks, wireless networks, or combinations thereof. The communication interface 935 can enable communications via any number of wireless broadband communication standards.

Accordingly, methods and systems described herein can be realized in hardware, software, or a combination of hardware and software. The methods and systems can be realized in a centralized fashion in at least one computer system or in a distributed fashion where different elements are spread across interconnected computer systems. Any kind of computer system or other apparatus adapted for carrying out the methods described herein can be employed.

The methods and systems described herein can also be embedded in a computer program product, which includes all the features enabling the implementation of the operations described herein and which, when loaded in a computer system, can carry out these operations. Computer program as used herein refers to an expression, in a machine-executable language, code or notation, of a set of machine-executable instructions intended to cause a device to perform a particular function, either directly or after one or more of a) conversion of a first language, code, or notation to another language, code, or notation; and b) reproduction of a first language, code, or notation.

While the systems and methods of operation have been described with reference to certain examples, it will be understood by those skilled in the art that various changes can be made and equivalents can be substituted without departing from the scope of the claims. Therefore, it is intended that the present methods and systems not be limited to the particular examples disclosed, but that the disclosed methods and systems include all embodiments falling within the scope of the appended claims.

What is claimed is:

1. A computing system comprising:
one or more processors; and
one or more storage devices that comprise instruction code that is executable by the one or more processors to cause the computing system to:
receive battery characteristic information associated with a battery of a vehicle;
receive vehicle usage information associated with the vehicle, wherein the vehicle usage information relates one or more of a speed and acceleration experienced by the vehicle with one or more vehicle operating periods;
receive vehicle environmental information, wherein the vehicle environmental information relates one or more environmental conditions to which the vehicle was exposed with one or more periods;
determine, via trained machine-learning logic and based on at least one of the battery characteristic information, the vehicle usage information, or the vehicle environmental information, a predicted battery health associated with the battery that is indicative of a current charge capacity of the battery relative to an original/rated charge capacity of the battery; and
communicate an indication of the predicted battery health.

2. The computing system according to claim 1, wherein the battery characteristic information specifies one or more of: the original/rated charge capacity of the battery, a battery type, a serial number, a number of times the battery was charged, and a charger type used to charge the battery.

3. The computing system according to claim 1. wherein the vehicle environmental information specifies one or more of: a temperature and a humidity to which the vehicle was exposed.

4. The computing system according to claim 1, wherein the instruction code that causes the computing system to receive the battery characteristic information associated with a battery of a vehicle comprises instruction code that causes the computing system to:
communicate vehicle identifying information that specifies a particular vehicle to a vehicle information server; and
receive, from the vehicle information server, battery characteristic information associated with the particular vehicle.

5. The computing system according to claim 1, wherein the instruction code that causes the computing system to receive the vehicle environmental information associated with the vehicle comprises instruction code that causes the computing system to:
communicate, to an environmental information server that stores environmental information associated with different regions and over different periods, a request for environmental information associated with one or more locations at which the vehicle was located during the one or more periods; and
receive, from the environmental information server, vehicle environment information associated with the one or more locations at which the vehicle was located during the one or more periods.

6. The computing system according to claim 1, wherein the instruction code that causes the computing system to determine, via trained machine-learning logic, the predicted battery health associated with the battery comprises instruction code that causes the computing system to:
input, to one or more nodes of an input layer of a neural network implemented by the trained machine-learning logic, a plurality of embeddings that respectively represent the battery characteristic information, the vehicle usage information, and the vehicle environmental information; and
receive, from one or more output layer nodes of the neural network, a battery health prediction indicative of a current charge capacity of the battery relative to an original/rated charge capacity of the battery.

7. The computing system according to claim 6, wherein the instruction code that causes the computing system to train the neural network, wherein the instruction code that causes the computing system to train the neural network comprises instruction code that causes the computing system to:
receive training data that comprises records, wherein each record relates a particular battery's health with corresponding battery characteristic information, vehicle usage information, and vehicle environmental information; and
iteratively input to the one or more nodes of the input layer of the neural network the battery characteristic information, the vehicle usage information, and the vehicle environmental information of each record as an embedding, and adjust weights and biases of the neural network using back and forward propagation techniques until the one or more output layer nodes of the neural network indicate a prediction of battery health that substantially matches the particular battery health associated with particular battery characteristic information, vehicle usage information, and vehicle environmental information being input to the neural network.

8. The computing system according to claim 7, wherein the instruction code that causes the computing system to receive the training data comprises instruction code that causes the computing system to:
receive the training data from a vehicle information server, wherein the vehicle information server comprises instruction code that causes the vehicle information server to:
receive, from a plurality of vehicles, one or more of kinematic characteristics, environmental characteristics, and peripheral usage characteristics stored within a storage device that is in communication with a controller of the vehicle.

9. The computing system according to claim 7, wherein the instruction code that causes the computing system to receive the training data comprises instruction code that causes the computing system to:
receive, from one or more vehicles and via a respective telematics device of the one or more vehicles, one or more of kinematic characteristics, environmental characteristics, and peripheral usage characteristics stored within the one or more vehicles.

10. A non-transitory computer-readable medium having stored thereon instruction code, which when executed by one or more processors of a computing system cause the computing system to:
receive battery characteristic information associated with a battery of a vehicle;
receive vehicle usage information associated with the vehicle, wherein the vehicle usage information relates one or more of a speed and acceleration experienced by the vehicle with one or more vehicle operating periods;
receive vehicle environmental information, wherein the vehicle environmental information relates one or more environmental conditions to which the vehicle was exposed with one or more periods;
determine, via trained machine-learning logic and based on at least one of the battery characteristic information, the vehicle usage information, or the vehicle environmental information, a predicted battery health associated with the battery that is indicative of a current charge capacity of the battery relative to an original/rated charge capacity of the battery; and
communicate an indication of the predicted battery health.

11. The non-transitory computer-readable medium according to claim 10, wherein the battery characteristic information specifies one or more of: the original/rated charge capacity of the battery, a battery type, a serial number, a number of times the battery was charged, and a charger type used to charge the battery.

12. The non-transitory computer-readable medium according to claim 10, wherein the vehicle environmental information specifies one or more of: a temperature and a humidity to which the vehicle was exposed.

13. The non-transitory computer-readable medium according to claim 10, wherein the instruction code that causes the computing system to receive the battery characteristic information associated with a battery of a vehicle comprises instruction code that causes the computing system to:
communicate vehicle identifying information that specifies a particular vehicle to a vehicle information server; and
receive, from the vehicle information server, battery characteristic information associated with the particular vehicle.

14. The non-transitory computer-readable medium according to claim 10, wherein the instruction code that causes the computing system to receive the vehicle environmental information associated with the vehicle comprises instruction code that causes the computing system to:
communicate, to an environmental information server that stores environmental information associated with different regions and over different periods, a request for environmental information associated with one or more locations at which the vehicle was located during the one or more periods; and
receive, from the environmental information server, vehicle environment information associated with the one or more locations at which the vehicle was located during the one or more periods.

15. The non-transitory computer-readable medium according to claim 10, wherein the instruction code that causes the computing system to determine, via trained machine-learning logic, the predicted battery health associated with the battery comprises instruction code that causes the computing system to:
input, to one or more nodes of an input layer of a neural network implemented by the trained machine-learning logic, a plurality of embeddings that respectively represent the battery characteristic information, the vehicle usage information, and the vehicle environmental information; and
receive, from one or more output layer nodes of the neural network, a battery health prediction indicative of a current charge capacity of the battery relative to an original/rated charge capacity of the battery.

16. The non-transitory computer-readable medium according to claim 15, wherein the instruction code that causes the computing system to train the neural network, wherein the instruction code that causes the computing system to train the neural network comprises instruction code that causes the computing system to:
receive training data that comprises records, wherein each record relates a particular battery's health with corresponding battery characteristic information, vehicle usage information, and vehicle environmental information; and
iteratively input to the one or more nodes of the input layer of the neural network the battery characteristic information, the vehicle usage information, and the vehicle environmental information of each record as an embedding, and adjust weights and biases of the neural network using back and forward propagation techniques until the one or more output layer nodes of the neural network indicate a prediction of battery health that substantially matches the particular battery health associated with particular battery characteristic information, vehicle usage information, and vehicle environmental information being input to the neural network.

17. The non-transitory computer-readable medium according to claim 16, wherein the instruction code that causes the computing system to receive the training data comprises instruction code that causes the computing system to:
receive the training data from a vehicle information server, wherein the vehicle information server comprises instruction code that causes the vehicle information server to:
receive, from a plurality of vehicles, one or more of kinematic characteristics, environmental characteristics, and peripheral usage characteristics stored within a storage device that is in communication with a controller of the vehicle.

18. The non-transitory computer-readable medium according to claim 16, wherein the instruction code that causes the computing system to receive the training data comprises instruction code that causes the computing system to:
receive, from one or more vehicles and via a respective telematics device of the one or more vehicles, one or more of kinematic characteristics, environmental characteristics, and peripheral usage characteristics stored within the one or more vehicles.

19. A computing-implemented method comprising:
receiving, by a computing system, battery characteristic information associated with a battery of a vehicle;
receiving, by the computing system, vehicle usage information associated with the vehicle, wherein the vehicle usage information relates one or more of a speed and acceleration experienced by the vehicle with one or more vehicle operating periods;
receiving, by the computing system, vehicle environmental information, wherein the vehicle environmental information relates one or more environmental conditions to which the vehicle was exposed with one or more periods;
determining, via trained machine-learning logic of the computing system and based on at least one of the battery characteristic information, the vehicle usage information, or the vehicle environmental information, a predicted battery health associated with the battery that is indicative of a current charge capacity of the battery relative to an original/rated charge capacity of the battery; and
communicating, by the computing system, an indication of the predicted battery health.

20. The computing-implemented method according to claim 19, wherein the battery characteristic information specifies one or more of: the original/rated charge capacity of the battery, a battery type, a serial number, a number of times the battery was charged, and a charger type used to charge the battery.
